(19) United States
(12) Patent Application Publication
(10) Pub. No.: US 2007/0070613 A1
(43) Pub. Date: Mar. 29, 2007

(54) Method of manufacturing high density printed circuit boad

(75) Inventor: Myung Sam Kang, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/526,688

(22) Filed: Sep. 26, 2006

(30) Foreign Application Priority Data
Sep. 27, 2005 (KR) 10-2005-0090020

(51) Int. Cl. H05K 1/14; H05K 1/00; H05K 1/11

(52) U.S. Cl. 361/803; 361/749

(57) ABSTRACT

Disclosed is a method of manufacturing a high density printed circuit board, in which a copper clad laminate is not used as a basic material, thus enabling the manufacture of a thin printed circuit board and solving the problems occurring in conventional methods of manufacturing a printed circuit board. The method of manufacturing the printed circuit board according to this invention includes forming a circuit pattern to a predetermined depth in one surface of a copper substrate; placing an insulating layer on the surface of the substrate having the circuit pattern; and etching the substrate, thus exposing the circuit pattern.

### BACKGROUND OF THE INVENTION

1. Field of the Invention

The present invention relates to a method of manufacturing a printed circuit board (PCB). More particularly, the present invention relates to a method of manufacturing a high density PCB, in which a copper clad laminate (CCL) is not used as a basic material, thus enabling manufacture of a thin PCB and solving the problems occurring in conventional PCB manufacturing methods.

2. Description of the Related Art

In conventional PCB manufacturing methods, a circuit formation process is classified as either a tenting (etching) process or an additive process.

The tenting process is a technique of forming a circuit pattern by forming an etching resist pattern on a copper foil formed to a predetermined thickness on a CCL and immersing the substrate in an etching solution to etch a portion of the copper foil other than the circuit.

The additive process, which is widely employed these days, is a technique of realizing a circuit pattern by forming a plating resist pattern on a CCL, forming a circuit portion through plating, and removing the plating resist.

Although the tenting process incurs a low manufacturing cost, it has limited use in the formation of a fine circuit pattern. As such, the technique proposed to overcome the above limitation is an additive process.

FIGS. 1A to 1D illustrate the process of manufacturing the PCB according to a conventional semi-additive technique.

In FIG. 1A, on the surface of the copper foil 12 of a CCL comprising a reinforced base sheet 11 and a copper foil 12, a plating resist 13 is applied and developed, thus forming a plating resist pattern.

Typically, the copper foil 12 of the CCL is 0.5˜3 μm thick. As the plating resist 13, a photosensitive dry film is used.

In FIG. 1B, a plating layer 14 is formed through electroplating. Upon the plating, the copper foil 12 functions as a seed layer. However, the plating layer 14, resulting from the plating process, cannot have a uniform thickness over the entire surface due to variation in the plating process.

In FIG. 1C, the plating resist 13 that remains after the completion of the plating process is stripped.

To this end, the substrate is immersed in a stripping solution, therefore removing the plating resist 13. At this time, however, there is a problem in which the plating resist 13 is not completely removed, but undesirably remains on the side wall of the plating layer 14.

In FIG. 1D, the portion of the copper foil 12 other than the circuit pattern is removed through soft etching such that only the circuit pattern remains, thereby forming a desired circuit pattern.

However, the above-mentioned additive technique suffers because it may increase the manufacturing cost, attributable to the use of the basic material or the complicated manufacturing process.

The manufacturing cost thus increased is problematic under present circumstances in which the fabrication cost of electronic parts is drastically decrease due to the increase in commercialization of the electronic parts.

In this regard, although various methods for manufacturing a high density PCB are disclosed in U.S. Pat. No. 5,872,338, they are more complicated and incur higher costs than conventional methods.

Therefore, a novel PCB manufacturing method, which has a simple manufacturing process and can decrease the manufacturing cost while realizing a fine circuit pattern, is required.

### SUMMARY OF THE INVENTION

Accordingly, an object of the present invention is to provide a method of manufacturing a PCB, without the use of a conventional CCL as a basic material.

Another object of the present invention is to provide a method of manufacturing a high density PCB, which realizes a simpler manufacturing process and can decrease the manufacturing cost.

A further object of the present invention is to provide a method of manufacturing a PCB, which can be used to make a thinner PCB.

A still further object of the present invention is to provide a method of manufacturing a PCB, which can form a fine circuit pattern having higher density.

In order to accomplish the above objects, the present invention provides a method of manufacturing a high density PCB, comprising preparing a copper substrate; applying etching resists on both surfaces of the substrate; forming an etching resist pattern on one surface of the substrate; etching the substrate to a predetermined depth, thus forming a circuit pattern; removing the etching resists; placing an insulating layer on the surface of the substrate having the circuit pattern; and etching the substrate, thus exposing the circuit pattern.

In addition, the present invention provides a method of manufacturing a high density PCB, comprising preparing a plurality of copper substrates, one surface of each of which has a circuit pattern formed to a predetermined depth; interposing an insulating layer between the circuit patterns of the substrates; forming via holes through the substrates; plating the substrates to fill the via holes; surface etching the substrates to expose the circuit patterns, thus forming a core layer; placing additional circuit layers on both surfaces of the core layer; and post-treating the outer layers of the substrates.

### BRIEF DESCRIPTION OF THE DRAWINGS

FIGS. 1A to 1D illustrate the process of manufacturing a PCB according to a conventional semi-additive technique;

FIGS. 2A to 2G illustrate the process of manufacturing a high density PCB according to the present invention;

FIGS. 3A to 3F illustrate the process of forming a core layer in the process of manufacturing the four-layer PCB according to the present invention; and

FIGS. 4A to 4F illustrate the process of forming additional layers in the process of manufacturing the four-layer PCB according to the present invention.

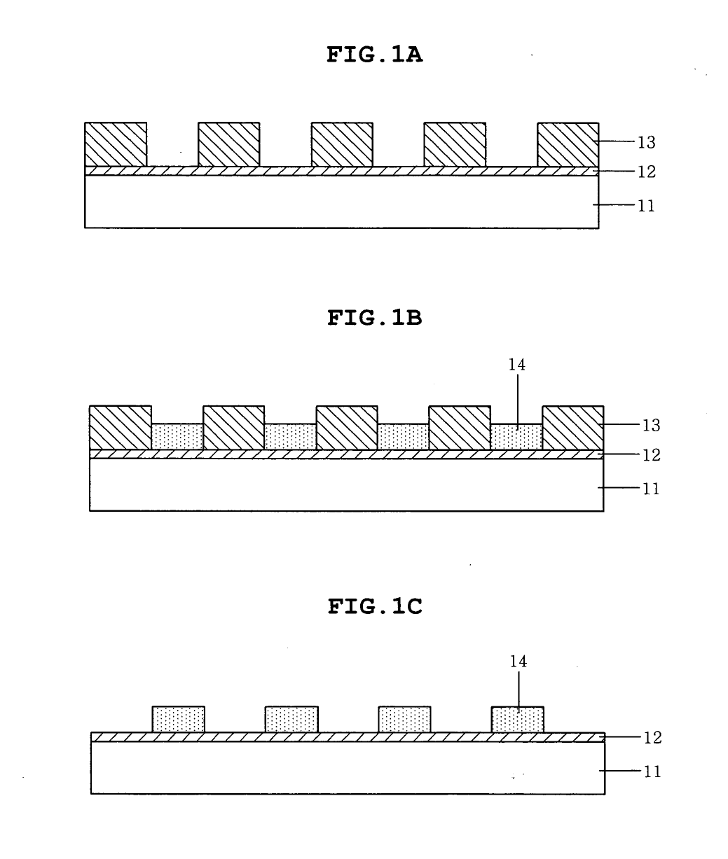

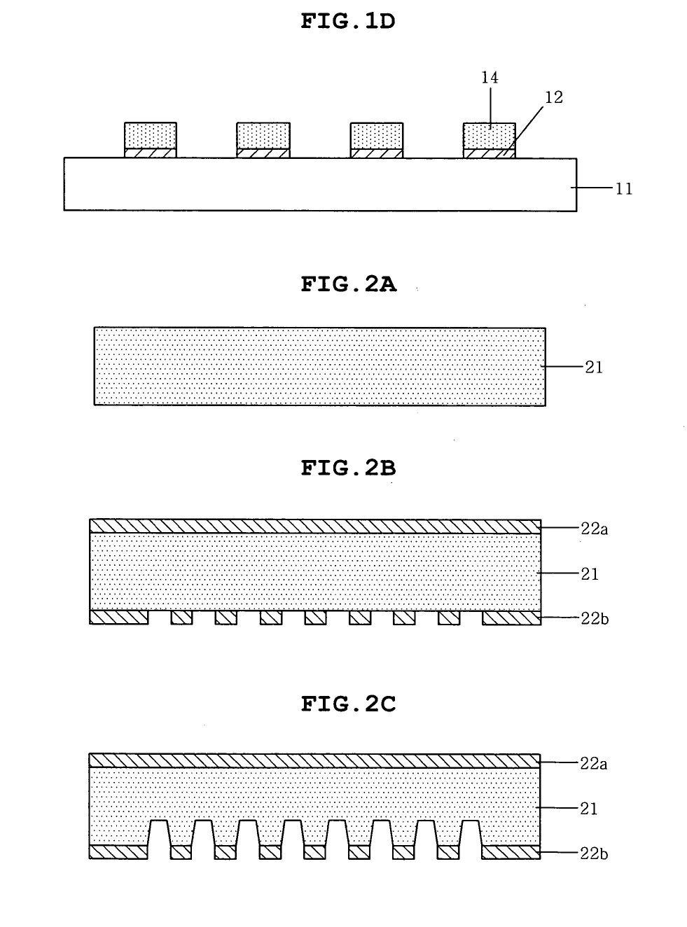

### DESCRIPTION OF THE PREFERRED EMBODIMENTS

Hereinafter, a detailed description will be given of the present invention, with reference to the appended drawings.

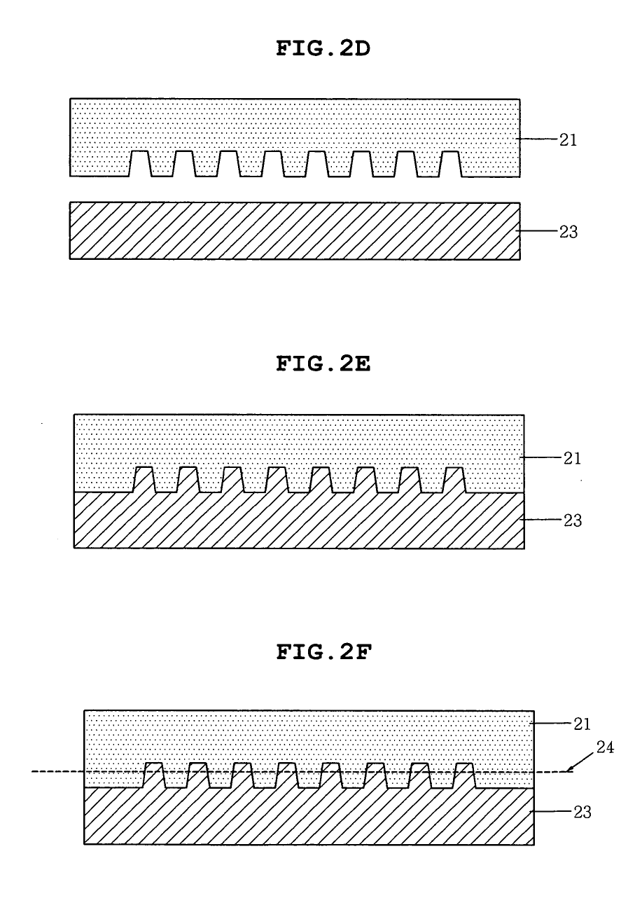

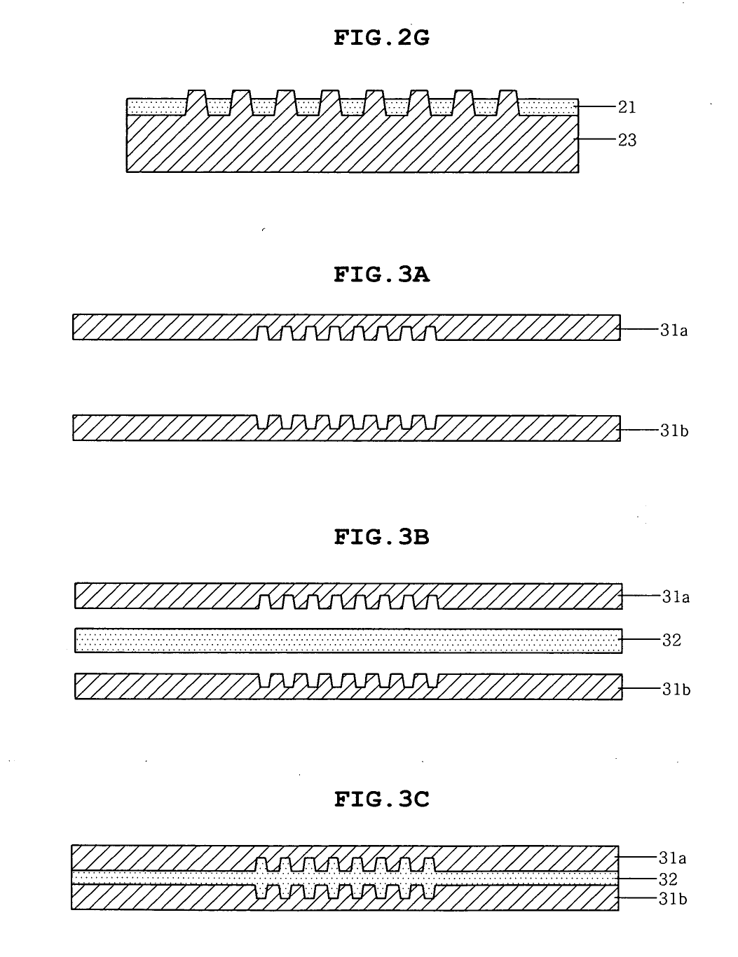

FIGS. 2A to 2G illustrate the process of manufacturing a high density PCB, according to the present invention. Referring to FIGS. 2A to 2G, the method of manufacturing the high density PCB, according to the present invention, is described below.

As shown in FIG. 2A, a copper substrate 21 is prepared. As such, the copper substrate 21 of the present invention, which is thicker than the copper foil of a CCL, used as a basic material in a conventional manufacturing method, preferably has a thickness of 40 μm or more.

In the PCB manufacturing method according to the present invention, a copper substrate 21 composed exclusively of copper is used, instead of the CCL comprising a reinforced base sheet and a copper foil. The copper substrate 21 may be formed of a material that is the same as the copper material used in the copper foil of the conventional CCL.

Further, the surface of the copper substrate 21 preferably has a predetermined roughness in order that various chemical and physical treatment procedures can be efficiently performed during the manufacturing process and adhesion to an insulting layer, which is provided in a subsequent procedure, can be increased.

In FIG. 2B, dry films 22a, 22b, acting as etching resists, for example, photosensitive etching resists, are applied on both surfaces of the substrate 21, one dry film 22b of which is exposed and developed, thus forming an etching resist pattern.

In FIG. 2C, the substrate 21 is immersed in an etching solution, thus forming a circuit pattern in the lower surface of the substrate 21. As such, the portion of the substrate having the dry film 22b thereon is not etched because the etching solution does not penetrate therethrough, whereas the portion of the substrate having no dry film 22bis etched, leading to the circuit pattern.

The substrate 21 should be etched somewhat deeper than the surface of the substrate, which is not etched but remains. In such a case, the etching process is preferably conducted such that the etching depth approaches the core portion of the substrate 21. The etching depth varies depending on the time period for which the substrate 21 is immersed in the etching solution.

After the etching process, the etching resists 22a, 22b are removed.

After the removal of the etching resists 22a, 22b, it is preferred that the surface of the substrate 21 having the circuit pattern be treated in order to increase adhesion to the subsequently formed insulating layer 23. The surface treatment includes, for example, blackening treatment or browning treatment.

As shown in FIG. 2D, the insulating layer 23 and the substrate 21 are disposed and held together at a precise position to align them. The insulating layer 23 preferably includes a prepreg, which is useful for interlayer insulation upon fabrication of a multilayered PCB, and exhibits appropriate adhesion upon a heating process. When the insulating layer 23 and the substrate 21 are held together, a rivet is preferably used.

The prepreg, which is a material obtained by impregnating a glass fiber material with an adhesive, is interposed between circuit layers having circuit patterns so as to function as an insulating layer between the circuit layers and as an adhesive layer therebetween.

After the insulating layer 23 is disposed as in FIG. 2D, the substrate 21 and the insulating layer 23 are heated and compressed relative to each other. Thereby, as shown in FIG. 2E, the upper surface of the insulating layer 23 is pressed into the circuit pattern of the substrate 21. Moreover, in the case where the insulating layer 23 is a prepreg, an adhesive exudes from the insulating layer 23 and therefore the substrate 21 and the insulating layer 23 are firmly attached to each other.

After the completion of the alignment of the insulating layer 23, the substrate 21 is immersed in the etching solution, and the substrate 21 is etched up to a dotted line 24 shown in FIG. 2F, such that the surface of the prepreg 23, which is pressed into the substrate 21 is exposed, thus baring the circuit pattern. In this case, since the prepreg is not a metal material, it never reacts with the etching solution. After the completion of the etching process, a single-sided PCB, in which the circuit pattern is formed on one surface of the insulating layer 23, is obtained, as shown in FIG. 2G. Further, it is preferred that the surface of the substrate be coated with a solder resist for protection of the circuit as the post-treatment.

Consequently, in the PCB manufacturing method mentioned above, since there is no process of removing a plating resist after a plating process, the problem, in which the plating resist remains on the side wall of the plating layer, is avoided from the outset.

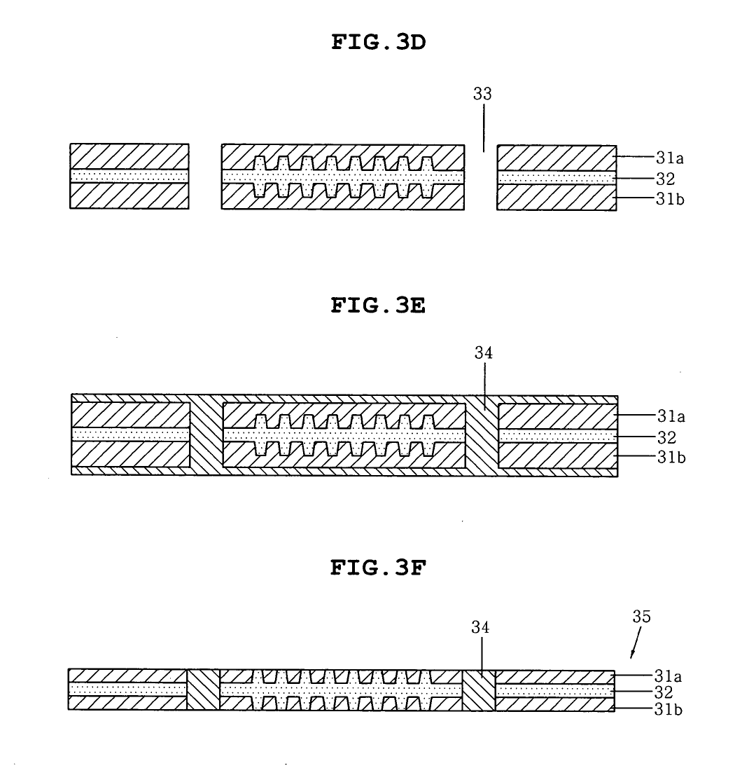

FIGS. 3A to 3F illustrate the process of forming a core layer in the process of manufacturing the four-layer PCB, according to the present invention.

As shown in FIG. 3A, copper substrates 31a, 31b, having circuit patterns that will be formed into a second layer circuit and a third layer circuit in respective first surfaces thereof, are prepared through a separate process.

The circuit pattern formation process may be conducted by applying the same processes as those shown in FIGS. 2A to 2C to the copper substrates 31a, 31b.

In FIG. 3B, the copper substrates 31a, 31b are disposed so that surfaces thereof, in which the circuit patterns are formed, are facing, and an insulating layer 32, for example, a prepreg, is interposed therebetween, such that respective layers are held together at a precise position. As such, respective layers are preferably held using rivets.

Before aligning the copper substrates 31a, 31b, they are preferably subjected to surface treatment, such as blackening treatment or browning treatment, in order to increase adhesion to the insulating layer 32.

In FIG. 3C, the copper substrates 31a, 31b thus disposed are aligned with the insulating layer 32, and the upper and lower surfaces thereof are heated and compressed relative to each other. Thereby, the upper and lower surfaces of the insulating layer 32 are pressed into the circuit patterns of the copper substrates 31a, 31b. In addition, since the adhesive component exudes from the insulating layer 32, the copper substrates 31a, 31b and the insulating layer 32 are firmly attached.

In FIG. 3D, via holes 33 for connection of a signal between the substrates 31a, 31b are formed through predetermined positions of the substrate using a drilling process. Upon the drilling process, the substrates 31a, 31b are preferably subjected to mechanical drilling using a CNC drill.

In FIG. 3E, the substrates are completely subjected to copper plating, thus forming a copper plating layer 34. While the inner wall of the via hole 33 is plated with the copper plating layer 34, the via hole 33 is filled therewith.

In FIG. 3F, after the plating process, the surfaces of the copper plating layer 34 and the copper substrates 31a, 31b are etched through surface etching, thus exposing the pattern of the insulating layer 32. Ultimately, a core layer 35, the upper and lower surfaces of which have the second layer and third layer circuit patterns of the four-layer PCB, respectively, is obtained.

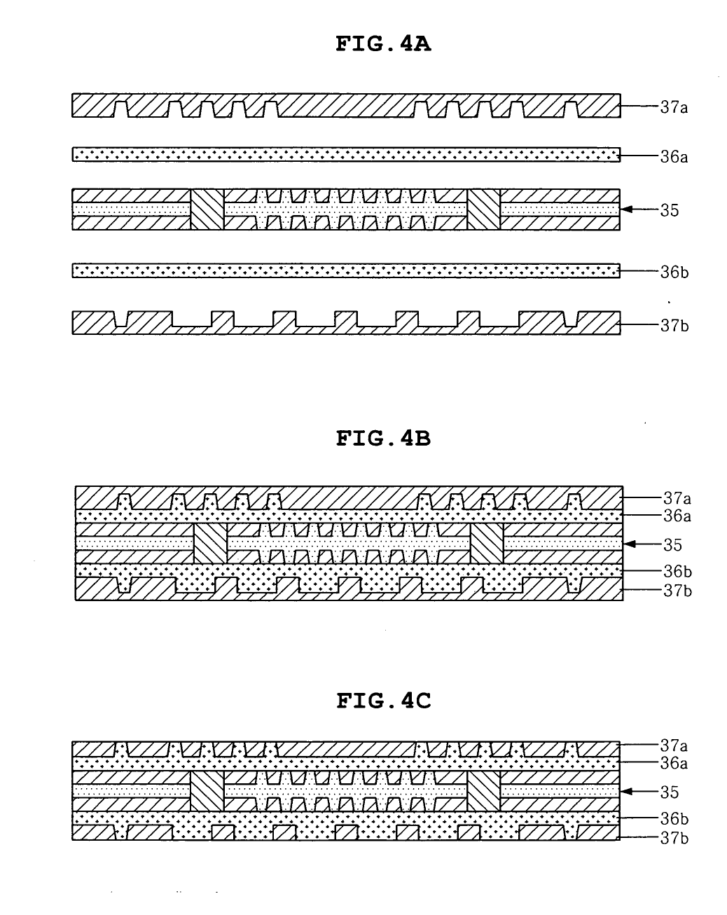

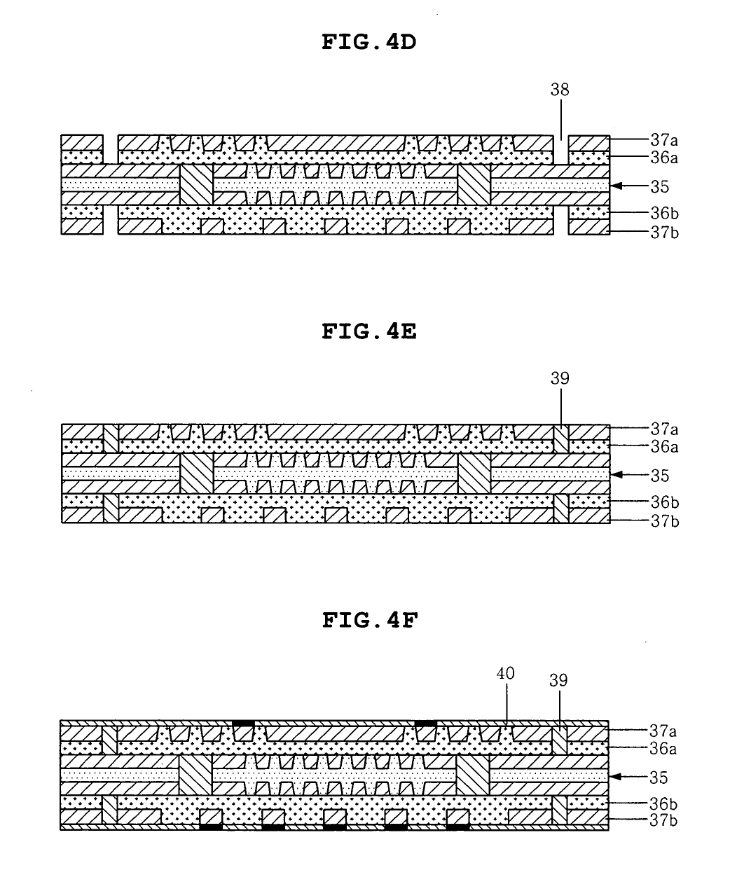

Turning now to FIGS. 4A to 4F, the process of forming additional layers in the four-layer PCB manufacturing process according to the present invention is illustrated.

First, copper substrates 37a, 37b, one surface of each of which has a circuit pattern, are prepared, and are then disposed at both sides of the core layer 35 formed through the processes of FIGS. 3A to 3F. Also, insulating layers 36a, 36b are provided between the copper substrates 37a, 37b, and thus all the layers are aligned and held. As such, respective layers are preferably held together using rivets.

The copper substrates 37a, 37b may include copper substrates prepared through the same process as that used in the formation of the copper substrates 31a, 31b of FIG. 3A. Further, the insulating layers 36a, 36b may include prepregs the same as that of the insulating layer 32.

The circuit patterns of the copper substrates 37a, 37b constitute the first layer and the fourth layer of a final product, and are designed so as to contain via hole portions for a laser process, described below, and a pad structure for connection of the via holes.

As in FIG. 4B, when the upper and lower surfaces of the substrates are heated and compressed relative to each other, the insulating layers 36a, 36b are pressed into the circuit patterns of the substrates and are thus firmly attached thereto.

Subsequently, as in FIG. 4C, the upper and lower surfaces of the substrates are etched, thus exposing the insulating layers 36a, 36b. In such a case, the etching process is conducted to the extent that short circuits of the circuit patterns of the substrates 37a, 37b do not occur due to the exposed insulating layers 36a, 36b. The extent of the etching process may be adjusted by controlling the time period during which the substrate is immersed in an etching solution.

In FIG. 4D, via holes 38 are processed to connect the second and third layer circuit patterns of the core layer 35 to the third and fourth layer circuit patterns. Such a via hole 38 may be formed through a laser process. The circuit pattern of the substrate 37aor 37b is formed so that the copper portion of the substrate 37a or 37b, corresponding to the position where the via hole 38 is formed, is completely removed through the etching process of FIG. 4C.

Accordingly, since the copper portion does not remain in the position where the via hole 38 is formed, the depth of the via hole 38 can be accurately adjusted through a laser drilling process, which makes fine processing possible.

In FIG. 4E, the via hole 38 is filled through the plating process.

In FIG. 4F, the application of a solder resist 40, as post-treatment, is conducted on the surfaces of the substrates to protect the circuits, thereby completing the high density four-layer PCB according to the present invention.

As described hereinbefore, the present invention provides a method of manufacturing a PCB. According to the present invention, the PCB manufacturing method does not require the use of a conventional CCL as a basic material, and realizes a manufacturing process that is simpler than a conventional semi-additive process, thus decreasing the substrate manufacturing cost.

According to the PCB manufacturing method of the present invention, defects caused upon the formation of the circuit pattern through a conventional semi-additive process, for example, short circuit, non-stripped plating resist, etc., may be solved.

According to the PCB manufacturing method of the present invention, a PCB can be made thin because a CCL is not used.

According to the PCB manufacturing method of the present invention, a PCB having a fine circuit pattern can be manufactured.

According to the PCB manufacturing method of the present invention, a problem with a conventional technique, in which a circuit pattern is removed from a reinforced base sheet after a plating resist is stripped upon the formation of a fine circuit pattern using chemical copper, may be overcome.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a high density printed circuit board, comprising:
forming a circuit pattern to a predetermined depth in one surface of a copper substrate;
placing an insulating layer on the surface of the substrate having the circuit pattern; and
etching the substrate, thus exposing the circuit pattern.

2. The method as set forth in claim 1, wherein the copper substrate has a thickness of 40 μm or more.

3. The method as set forth in claim 1, wherein the forming the circuit pattern to the predetermined depth in one surface of the copper substrate comprises:
applying etching resists on both surfaces of the substrate;
forming an etching resist pattern on one surface of the substrate;
etching the substrate to a predetermined depth, thus forming the circuit pattern; and
removing the etching resists.

4. The method as set forth in claim 1, wherein the placing the insulating layer comprises:
surface treating the insulating layer; and
heating and compressing the insulating layer to the surface of the substrate having the circuit pattern.

5. A method of manufacturing a high density printed circuit board, comprising:
preparing a plurality of copper substrates, one surface of each of which has a circuit pattern formed to a predetermined depth;
interposing an insulating layer between the circuit patterns of the substrates;
forming via holes through the substrates;
plating the substrates to fill the via holes;
surface etching the substrates to expose the circuit patterns, thus forming a core layer;
placing additional circuit layers on both surfaces of the core layer; and
post-treating outer layers of the substrates.

6. The method as set forth in claim 5, wherein the copper substrate has a thickness of 40 μm or more.

7. The method as set forth in claim 5, wherein an additional copper substrate has a thickness of 40 μm or more.

8. The method as set forth in claim 5, wherein the placing the additional circuit layers comprises:
preparing an insulating layer and an additional copper substrate having a circuit pattern formed to a predetermined thickness in one surface thereof;
placing the insulating layer and the additional copper substrate on the core layer;
exposing the circuit pattern of the additional copper substrate through etching;
forming a via hole through the additional copper substrate; and
plating the substrate to plate the via hole.

9. The method as set forth in claim 5, wherein the interposing the insulating layer comprises blackening or browning the surface of the copper substrate having the circuit pattern formed to the predetermined depth.

10. The method as set forth in claim 5, wherein the post-treating comprises applying a solder resist on an outer circuit of an additional copper substrate.
